(19) United States
(12) Patent Application Publication
(10) Pub. No.: US 2025/0386495 A1
(43) Pub. Date: Dec. 18, 2025

(54) METHOD FOR MANUFACTURING A THREE-DIMENSIONAL MEMORY

(71) Applicant: Hangzhou HFC Semiconductor Co., Hangzhou (CN)

(72) Inventors: Youming LIU, Hangzhou (CN); Hokmin HO, Hangzhou (CN)

(73) Assignee: Hangzhou HFC Semiconductor Co., Hangzhou (CN)

(21) Appl. No.: 18/761,271

(22) Filed: Jul. 1, 2024

(30) Foreign Application Priority Data
Jun. 18, 2024 (CN) 202410791387.0

(51) Int. Cl. H10B 43/27; H10B 43/10

(52) U.S. Cl. CPC H10B 43/27; H10B 43/10

(57) ABSTRACT

The present application discloses a method for manufacturing a three-dimensional memory and relates to the technical field of semiconductors. The manufacturing method includes: providing a substrate; forming a first isolation structure and a second isolation structure in the substrate, wherein the first isolation structure vertically intersects the second isolation structure, a plurality of vertical channels is formed in the substrate, and a depth of the second isolation structure is less than a depth of the first isolation structure; forming a source in the substrate at a bottom of the second isolation structure, wherein an entire row of the vertical channels shares a same source; sequentially forming a gate dielectric layer and a metal gate around the vertical channel, wherein the metal gate is distributed vertically to the source; and forming a drain on the vertical channel, wherein the drain is arranged in parallel with the source.

### CROSS REFERENCE TO RELATED APPLICATION

This application claims the benefit of and priority from Chinese Patent Application No. 202410791387.0, filed on Jun. 18, 2024, the entire disclosure of which is incorporated herein by reference for all purposes.

### TECHNICAL FIELD

The present application relates to the technical field of semiconductor technology, and in particular, relates to a method for manufacturing a three-dimensional memory.

### BACKGROUND

NOR Flash is a non-volatile memory. Its structural storage units are arranged in parallel and addressed in rows and columns. The minimum addressing unit is a byte. It is named NOR Flash because its logic circuit is similar to a “NOR gate”. It is characterized by high reading speed, random access capability, and high writing endurance. Its high reading speed makes it very suitable for applications that require fast data reading, such as code storage for microcontrollers or embedded processors.

### SUMMARY

One or more embodiments of the present application provides a method for manufacturing a three-dimensional memory, which at least includes: providing a substrate; forming a first isolation structure and a second isolation structure in the substrate, wherein the first isolation structure vertically intersects the second isolation structure, a plurality of vertical channels is formed in the substrate, and a depth of the second isolation structure is less than a depth of the first isolation structure; forming a source in the substrate at a bottom of the second isolation structure, wherein an entire row of the vertical channels shares a same source; sequentially forming a gate dielectric layer and a metal gate around the vertical channel, wherein the metal gate is distributed vertically to the source; and forming a drain on the vertical channel, wherein the drain is arranged in parallel with the source.

In one or more exemplary embodiments of the present application, the manufacturing method further includes: after the first isolation structure is formed, doping the substrate to form a source doping region, wherein a depth of the source doping region is less than a depth of the first isolation structure; etching back the first isolation structure through selective etching to form a first recess; and forming a hard mask layer in the first recess.

In one or more exemplary embodiments of the present application, the manufacturing method further includes: forming a patterned photoresist layer on the substrate and the hard mask layer, wherein a plurality of elongated openings is provided on the patterned photoresist layer, and the elongated openings are perpendicular to the first isolation structure; etching the substrate and the hard mask layer with the patterned photoresist layer as a mask to form a groove, wherein a bottom of the groove is located in the source doping region; forming a protective layer on a sidewall of the groove, wherein the protective layer exposes the substrate at the bottom of the groove; forming a metal layer in the groove; annealing the metal layer to form the source; and removing an unreacted part of the metal layer.

In one or more exemplary embodiments of the present application, the manufacturing method further includes: after the source is formed, depositing an insulating material in the groove to form the second isolation structure; selectively etching back the second isolation structure and the protective layer, such that a surface of the second isolation structure is lower than a surface of the substrate, so as to form a second recess; and forming a spacer structure on a sidewall of the vertical channel exposed by the second recess.

In one or more exemplary embodiments of the present application, forming the metal gate includes: after the spacer structure is formed, removing a part of the second isolation structure, a part of the protective layer, and a part of the first isolation structure to form an opening, wherein a bottom of the opening is flush with a surface of the source doping region; forming a gate dielectric layer around the vertical channel exposed by the opening; completely filling the opening with a metal material layer; and etching the metal material layer along a direction perpendicular to the first isolation structure to form the metal gate.

In one or more exemplary embodiments of the present application, forming the drain includes: after the opening is filled with the metal material layer, doping an end of the vertical channel away from the source to form a drain doping region; after the metal gates are formed, forming an insulating material layer between the metal gates, and forming an interlayer dielectric layer on the insulating material layer, the metal gates, and the substrate; forming a conductive plug in the interlayer dielectric layer, wherein the conductive plug is connected to the drain doped region; and forming a drain on the interlayer dielectric layer and the conductive plug, and the entire row of the vertical channels shares the drain.

In one or more exemplary embodiments of the present application, a plane where a bottom of the drain doping region is located coincides with a plane where a top of the metal gate is located, a doping type of the drain doping region and a doping type of the source doping region are opposite to a doping type of the vertical channel, and the drain doping region and the source doping region have a same doping concentration.

In one or more exemplary embodiments of the present application, a minimum area of a storage unit of the memory is 4F².

In one or more exemplary embodiments of the present application, starting from a surface of the vertical channel, the gate dielectric layer includes a tunneling layer, a storage layer, a buffer layer, and a blocking layer.

In one or more exemplary embodiments of the present application, the tunneling layer includes a first tunneling layer, a second tunneling layer, and a third tunneling layer formed in sequence, the first tunneling layer, the third tunneling layer, and the buffer layer are silicon oxide layers, the second tunneling layer and the storage layer are silicon nitride layers, and the barrier layer is an aluminum oxide layer.

### BRIEF DESCRIPTION OF DRAWINGS

In order to more clearly illustrate the technical solutions of the embodiments of the present application, the accompanying drawings required for describing the embodiments will be briefly introduced below. Please note, the accompanying drawings described below are only some embodiments of the present application. For ordinary technicians in this field, other accompanying drawings can be obtained based on these accompanying drawings without needing creative work.

FIG. 1 is a schematic diagram of a three-dimensional memory according to one or more exemplary embodiments.

FIG. 2 is a schematic diagram of a substrate In one or more exemplary embodiments.

FIG. 3 is a schematic diagram of forming an isolation trench in a substrate according to one or more exemplary embodiments.

FIG. 4 is a schematic diagram of forming a first isolation structure and a source doping region in a substrate according to one or more exemplary embodiments.

FIG. 5 is a schematic diagram of etching back a first isolation structure to form a first recess according to one or more exemplary embodiments.

FIG. 6 is a schematic diagram of forming a hard mask layer in a first recess according to one or more exemplary embodiments.

FIG. 7 is a schematic diagram of forming a groove according to one or more exemplary embodiments.

FIG. 8 is a cross-sectional view of FIG. 7 along a direction A-A.

FIG. 9 is a cross-sectional view of FIG. 7 along a direction B-B.

FIG. 10 is a schematic diagram of a protective layer formed and etched according to one or more exemplary embodiments.

FIG. 11 is a cross-sectional view of FIG. 10 along a direction A-A.

FIG. 12 is a schematic diagram of forming a metal layer according to one or more exemplary embodiments.

FIG. 13 is a schematic diagram of forming a source after annealing according to one or more exemplary embodiments.

FIG. 14 is a schematic diagram of removing the unreacted metal layer according to one or more exemplary embodiments.

FIG. 15 is a cross-sectional view of FIG. 14 along a direction A-A.

FIG. 16 is a cross-sectional view of FIG. 14 along a direction B-B.

FIG. 17 is a cross-sectional view of FIG. 14 along a direction C-C.

FIG. 18 is a schematic diagram of forming a second isolation structure according to one or more exemplary embodiments.

FIG. 19 is a schematic diagram of forming a spacer structure on a second isolation structure according to one or more exemplary embodiments.

FIG. 20 is a cross-sectional view of FIG. 19 along a direction A-A.

FIG. 21 is a schematic diagram of removing a part of a first isolation structure and a second isolation structure to form an opening according to one or more exemplary embodiments.

FIG. 22 is a cross-sectional view of FIG. 21 along a direction A-A.

FIG. 23 is a cross-sectional view of FIG. 21 along a direction B-B.

FIG. 24 is a cross-sectional view of FIG. 21 along a direction C-C.

FIG. 25 is a schematic diagram of forming a gate dielectric layer around a vertical channel according to one or more exemplary embodiments.

FIG. 26 is a schematic cross-sectional view of a gate dielectric layer according to one or more exemplary embodiments.

FIG. 27 is a schematic diagram of forming a metal material layer in an opening according to one or more exemplary embodiments.

FIG. 28 is a cross-sectional view of FIG. 27 along a direction A-A.

FIG. 29 is a schematic diagram of forming a metal gate according to one or more exemplary embodiments.

FIG. 30 is a cross-sectional view of FIG. 29 along a direction A-A.

FIG. 31 is a schematic diagram of depositing insulating material between metal gates according to one or more exemplary embodiments.

FIG. 32 is a schematic diagram of forming an interlayer dielectric layer and conductive plugs according to one or more exemplary embodiments.

FIG. 33 is a schematic diagram of forming a drain according to one or more exemplary embodiments.

FIG. 34 is a cross-sectional view of FIG. 33 along a direction A-A.

FIG. 35 is a NOR flash memory array and equivalent circuit diagram.

### DESCRIPTION OF REFERENCE NUMBERS

substrate 10; isolation trench 110; first isolation structure 11; first recess 12; hard mask layer 13; groove 14; vertical channel 15; protective layer 16; metal layer 17; source 18; second isolation structure 19; spacer structure 20; opening 21; gate dielectric layer 22; tunneling layer 221; storage layer 222; buffer layer 223; barrier layer 224; first tunneling layer 2211; second tunneling layer 2212; third tunneling layer 2213; metal gate 23; metal material layer 231; 24. gap; insulating material layer 25; interlayer dielectric layer 26; conductive plug 27; drain 28; source doping region 101; drain doping region 102.

### DESCRIPTION OF EMBODIMENTS

The following describes the embodiments of the present application through specific examples, and those skilled in the art can easily understand other advantages and effects of the present application from the contents disclosed in this specification. The present application can also be implemented or applied through other different specific embodiments, and the details in this specification can also be modified or changed in various ways based on different viewpoints and applications without departing from the spirit of the present application.

It should be noted that the illustrations provided in these embodiments are only used to illustrate the basic concept of the present application in a schematic manner. Therefore, the drawings only show components related to the present application rather than being drawn according to the number, shape, and size of components in actual implementation. In actual implementation, the type, quantity, and scale of each component may be changed arbitrarily, and the component layout may also be more complicated.

In the present application, it should be noted that, if the terms “center”, “upper”, “lower”, “left”, “right”, “vertical”, “horizontal”, “inner”, “outer”, etc. appear, the orientation or position relationship indicated by them is based on the orientation or position relationship shown in the drawings, and is only for the convenience of describing the present application and simplifying the description, rather than indicating or implying that the device or element referred to must have a specific orientation, be constructed and operated in a specific orientation, and therefore cannot be understood as a limitation on the present application. In addition, if the terms “first” and “second” appear, they are only used for description and distinction purposes, and cannot be understood as indicating or implying relative importance.

With the rapid development of new-generation information technologies such as 5G, artificial intelligence (AI), and the Internet of Things (IoT), massive and extensive data needs to be stored and processed, and the demand for semiconductor memory is also growing rapidly. On today's wide variety of mobile terminals, such as wearable devices, small-sized, large-capacity embedded storage is required. There are more and more new demands for NOR Flash, which strongly requires new technological advances in NOR Flash. At present, the structure of NOR Flash is generally planar, and the planar structure is limited by the process node, resulting in a limited density of flash memory units in flash memory devices, which makes the flash memory devices less integrated and larger in size.

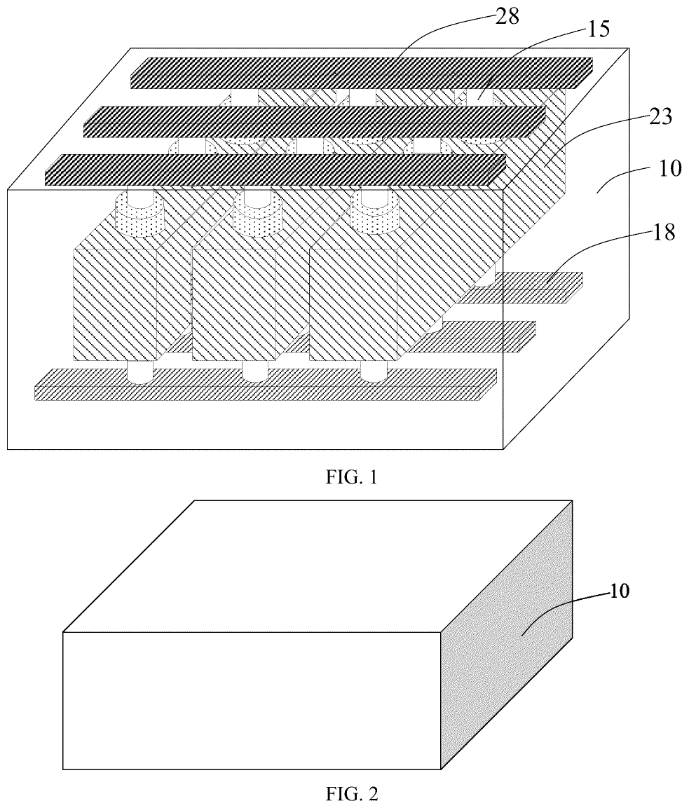

Please refer to FIG. 1, the present application provides a three-dimensional memory. For example, the memory is a NOR Flash. In one or more embodiments, the memory at least includes a substrate 10, a vertical channel 15, a source 18, a metal gate 23, and a drain 28. The vertical channel 15, the source 18, and the metal gate 23 are arranged in the substrate 10. The drain 28 is arranged on the substrate 10. The drain 28 and the source 18 are respectively arranged at two ends of the vertical channel 15. The drain 28 is arranged in parallel with the source 18. The metal gate 23 is arranged perpendicular to the drain 28 and the source 18. The metal gate 23 fully surrounds the vertical channel 15, which may improve the performance of the memory. In one or more embodiments, by forming a three-dimensional memory, it is possible to break through the process node limitation, increase the density of the flash memory unit, and improve the integration of the memory, thereby meeting the application of the memory in the new generation of information technology.

Please refer to FIG. 1 and FIG. 2, In one or more exemplary embodiments of the present application, a substrate 10 is first provided. The substrate 10 is made of any applicable semiconductor material. For example, the substrate 10 is a substrate made of sapphire, silicon wafer, silicon carbide (SiC), gallium nitride (GaN), aluminum nitride (AlN), indium nitride (InN), silicon germanium (GeSi), or the like. The substrate 10 may also include a stacked structure composed of the above-mentioned semiconductor materials, which can be selected according to the manufacturing requirements of the semiconductor device. In one or more exemplary embodiments, the substrate 10 is a single crystal silicon substrate. For example, the substrate 10 is a P-type substrate or an N-type substrate. This application does not make specific restrictions, and the selection is made according to the manufacturing requirements of the memory.

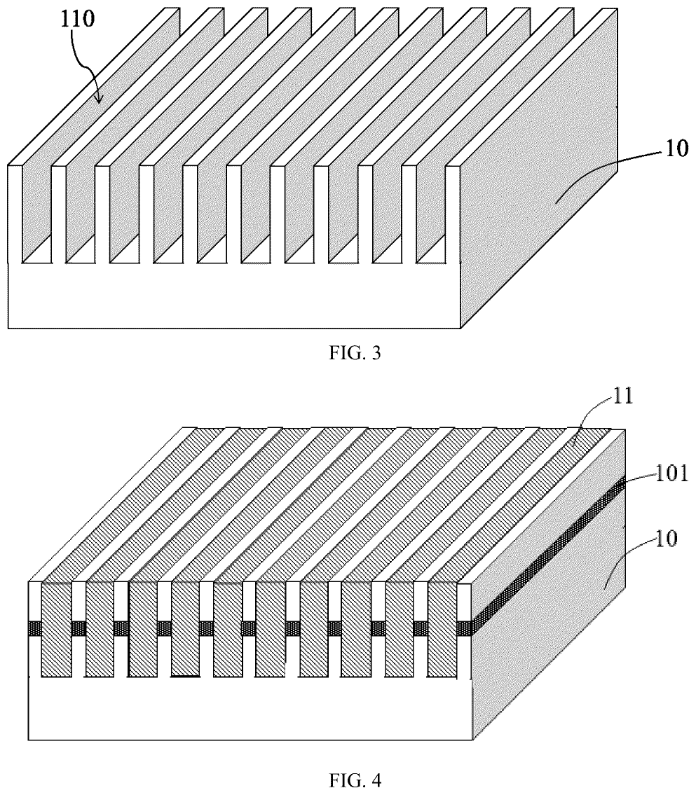

Please refer to FIG. 2 and FIG. 3, In one or more exemplary embodiments of the present application, a part of the substrate 10 is etched to form a plurality of isolation trenches 110 in the substrate 10. In one or more exemplary embodiments, a patterned photoresist layer (not shown in the figure) is formed on the substrate 10, and a plurality of elongated openings are provided on the patterned photoresist layer. For example, the patterned photoresist layer is used as a mask to perform dry etching in a direction toward the substrate 10 to form a plurality of isolation trenches 110. After the isolation trenches 110 are formed, the patterned photoresist layer is removed through wet cleaning or ashing process. In one or more exemplary embodiments, a part of the substrate 10 is removed by wet etching or a process combining wet etching and dry etching. In one or more exemplary embodiments, the formed isolation trenches 110 have the same width and the same depth, and the isolation trenches 110 are equidistantly distributed, that is, the distance between two adjacent isolation trenches 110 is equal.

Please refer to FIG. 3 and FIG. 4, In one or more exemplary embodiments of the present application, after the isolation trenches 110 are formed, an isolation dielectric is deposited in the isolation trenches 110 until the isolation dielectric completely fills the isolation trenches 110. In one or more exemplary embodiments, before the isolation dielectric is deposited, the isolation trenches is subjected to thermal oxidation treatment to round the corners at the bottom of the isolation trenches, which may reduce the tip leakage phenomenon. In one or more exemplary embodiments, the isolation dielectric is made of an insulating material, such as silicon dioxide, etc. The present application does not limit the deposition method of the isolation dielectric. In one or more exemplary embodiments, the isolation dielectric is formed in the isolation trenches 110 through deposition methods, such as chemical vapor deposition (CVD), high aspect ratio process chemical vapor deposition (HARP-CVD), or the like. After the isolation dielectric is deposited, the isolation dielectric is planarized through a planarization process, such as chemical mechanical polishing (CMP), with the substrate 10 as a grinding stop layer, to obtain a first isolation structure 11. At this time, the upper surface of the first isolation structure 11 is flush with the upper surface of the substrate 10.

Please refer to FIG. 4, In one or more exemplary embodiments of the present application, after the first isolation structure 11 is formed, the substrate 10 is doped to form a source doping region 101, and then the dopant ions are activated by rapid high temperature thermal annealing to reduce the resistance of the source formed subsequently. The type of the dopant ions in the source doping region 101 is opposite to the doping type of the substrate 10. In one or more exemplary embodiments, the source doping region 101 is formed by ion implantation technology. The implantation depth and implantation range of the source doping region 101 can be controlled by controlling the implantation energy. The depth of the source doping region 101 is less than the depth of the first isolation structure 11. For example, the depth of the source doping region 101 is one third to two thirds of the depth of the first isolation structure 11.

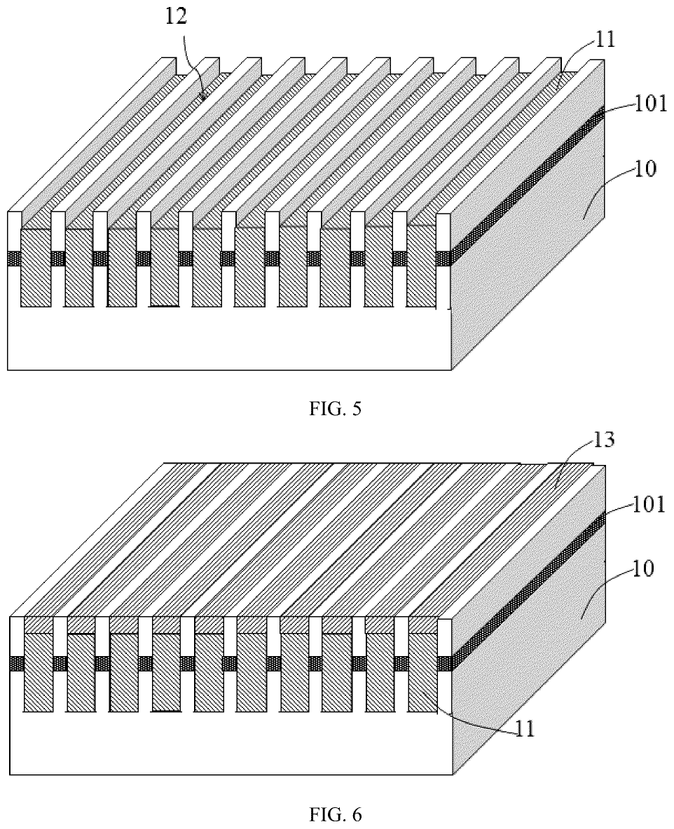

Please refer to FIG. 4 and FIG. 5, In one or more exemplary embodiments of the present application, after the first isolation structure 11 is formed, the first isolation structure 11 is etched back to form a first recess 12 on the first isolation structure 11. In one or more exemplary embodiments, for example, selective dry etching or selective wet etching is used to remove only a part of the isolation medium at the top of the first isolation structure 11, and the substrate 10 is not etched. The depth of the first recess 12 is less than the depth of the source doping region 101. Through selective etching, one photoresist can be reduced, the manufacturing process can be simplified, the manufacturing speed can be accelerated, and the cost can be reduced.

Please refer to FIG. 5 and FIG. 6, In one or more exemplary embodiments of the present application, after the first recess 12 is formed, a hard mask layer 13 is deposited on the first recess 12 and the substrate 10 until the hard mask layer 13 completely fills the first recess 12. In one or more exemplary embodiments, the hard mask layer 13 is made of a material different from that of the isolation medium. For example, the hard mask layer 13 is made of silicon nitride and is formed by a method such as low pressure chemical vapor deposition (LPCVD) or plasma enhanced chemical vapor deposition (PECVD), which may improve the quality of the hard mask layer 13. After the hard mask layer 13 is deposited, the hard mask layer is planarized through a planarization process, such as chemical mechanical polishing, with the substrate as a grinding stop layer. After planarization, the upper surface of the hard mask layer 13 is flush with the upper surface of the substrate 10.

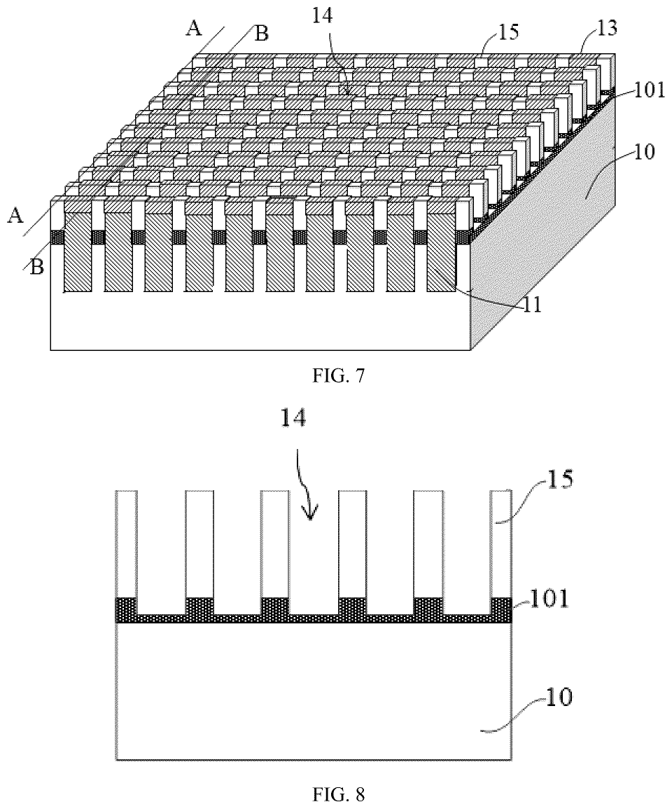

Please refer to FIG. 6 and FIG. 7, In one or more exemplary embodiments of the present application, after the hard mask layer is formed, a patterned photoresist layer (not shown in the figure) is formed on the substrate 10. A plurality of elongated openings is provided in the patterned photoresist layer, and the elongated openings are perpendicular to the extension direction of the first isolation structure 11. For example, etching, such as dry etching, is performed in a direction toward the substrate 10 with the patterned photoresist layer as a mask, to form a plurality of grooves 14. After the grooves 14 are formed, the patterned photoresist layer is removed by wet cleaning or ashing process. In one or more exemplary embodiments, wet etching or a combination of wet etching and dry etching is used to remove part of the substrate 10.

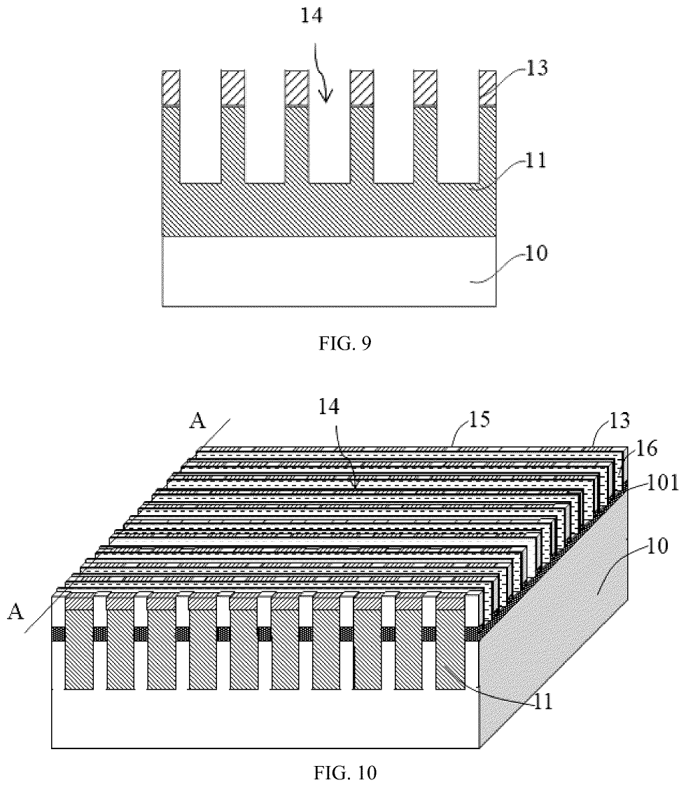

Please refer to FIG. 7 to FIG. 9, FIG. 8 is a cross-sectional view of FIG. 7 along a direction A-A, and FIG. 9 is a cross-sectional view of FIG. 7 along a direction B-B. In one or more exemplary embodiments, the grooves 14 are distributed vertically to the first isolation structure 11, and the bottom of the groove 14 is located in the source doping region 101. The formed grooves 14 have the same width and the same depth and are equidistantly distributed. In the process of forming the groove 14 and the first isolation structure 11, a plurality of vertical channels 15 are formed on the substrate 10 through two etchings. The vertical channels 15 are distributed in an array, and the depth of the vertical channel 15 is less than the depth of the first isolation structure 11. In the etching process, by controlling the range and the condition, the shape of the vertical channel 15 is, for example, a cylinder or a prism. In one or more exemplary embodiments, the shape of the vertical channel 15 is a cylinder, but for the sake of clarity of the picture and ease of description, the accompanying drawings are shown in a cubic shape. In one or more exemplary embodiments, by forming multiple vertical channels used to form a three-dimensional memory, the density of the flash memory unit may be increased, and the integration of the memory may be improved. In one or more exemplary embodiments, the vertical channel is a single crystal silicon channel, which may improve the performance of the memory.

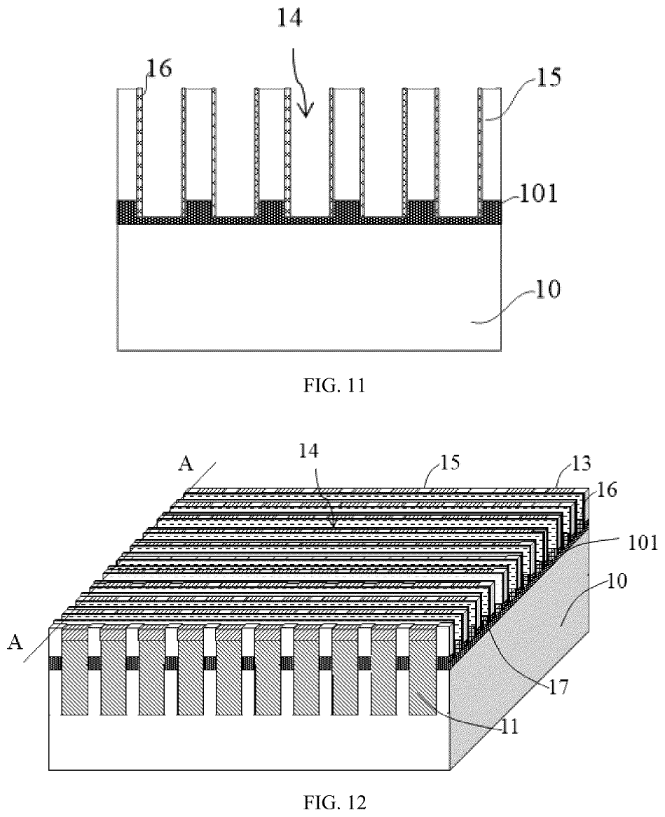

Please refer to FIG. 7, and FIG. 10 to FIG. 11, FIG. 11 is a cross-sectional view of FIG. 10 along a direction A-A. After the groove 14 is formed, a protective layer 16 is formed on the substrate 10 and at the bottom and the sidewalls of the groove 14. The protective layer 16 is, for example, a silicon oxide layer, and is formed, for example, by methods, such as atomic layer deposition (ALD), etc. The present application does not limit the thickness of the protective layer 16, so long as it meets the manufacturing requirements. After the protective layer 16 is formed, vertical etching through dry etching is conducted while the bias voltage during the etching process is controlled, to remove the protective layer 16 on the substrate 10 and at the bottom of the groove 14, and only retain the protective layer 16 on the sidewalls of the groove 14 to protect the vertical channel 15 in the subsequent process of forming the source. In one or more exemplary embodiments, by vertical etching, one photoresist may be reduced, thereby reducing the manufacturing cost.

Please refer to FIG. 10 and FIG. 12, In one or more exemplary embodiments of the present application, after the protective layer 16 is formed, a metal material is deposited at the bottom of the groove 14 to form a metal layer 17. For example, the metal material in the metal layer 17 is at least one of cobalt, nickel, tungsten, titanium, and platinum. The metal layer 17 is formed, for example, by a method such as physical vapor deposition (PVD), and the thickness of the metal layer 17 is, for example, 10 nm to 30 nm to ensure the need for subsequent formation of the source.

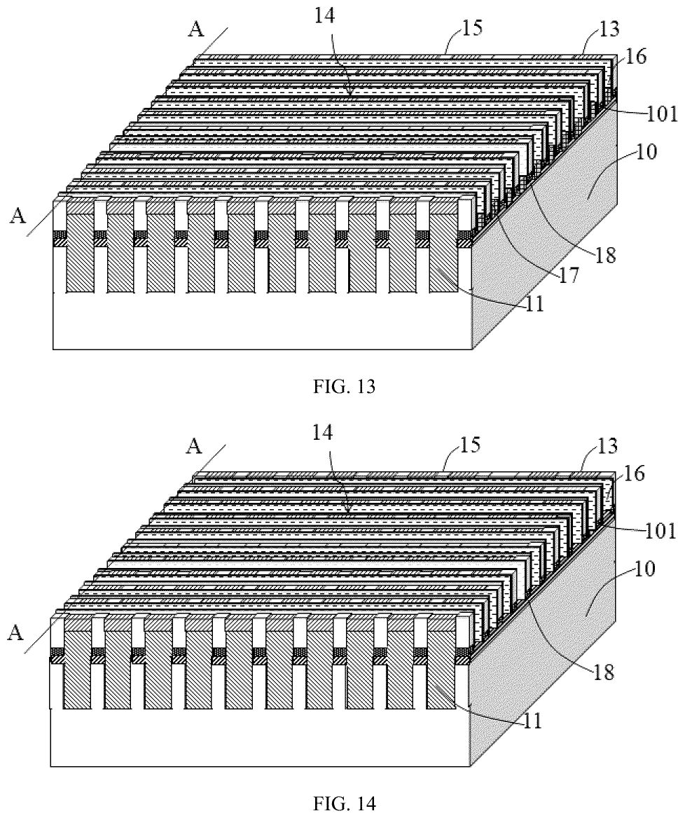

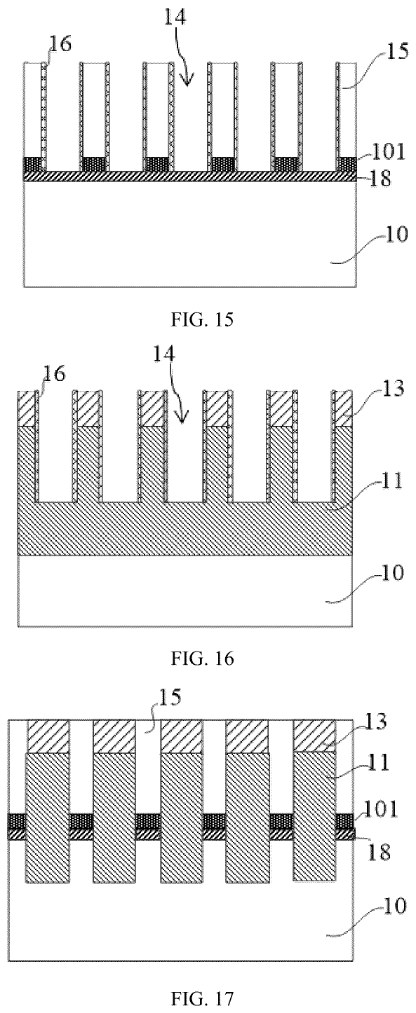

Please refer to FIG. 12 to FIG. 17, FIG. 15 is a cross-sectional view of FIG. 14 along a direction A-A, FIG. 16 is a cross-sectional view of FIG. 14 along a direction B-B, and FIG. 17 is a cross-sectional view of FIG. 14 along a direction C-C. After the metal layer 17 is formed, the metal material in the metal layer 17 reacts with the silicon in the substrate 10 through annealing to form a metal silicide layer, while the metal material does not react with the silicon oxide in the protective layer 16. For example, the unreacted metal layer 17 is removed by wet etching, and the formed metal silicide layer is defined as the source 18. During the annealing process, the metal material simultaneously diffuses to the bottom of the vertical channel 15 and reacts with the substrate 10 at the bottom of the vertical channel 15 to form a metal silicide layer. That is, along a direction A-A of FIG. 14, the source 18 has an elongated shape, and in a direction B-B, no source is formed under the hard mask layer 13. In a direction C-C, the sources of the storage units in different rows are arranged at intervals, that is, the entire row of multiple vertical channels 15 formed subsequently share the same source 18. In the present application, the source doping region 101 is at least disposed between the source 18 and the vertical channel 15 to reduce the resistance of the source 18 and improve the electrical performance of the memory device. In one or more exemplary embodiments, by sharing the source, no extra wiring is required, the manufacturing process may be simplified, and the connection performance may be improved.

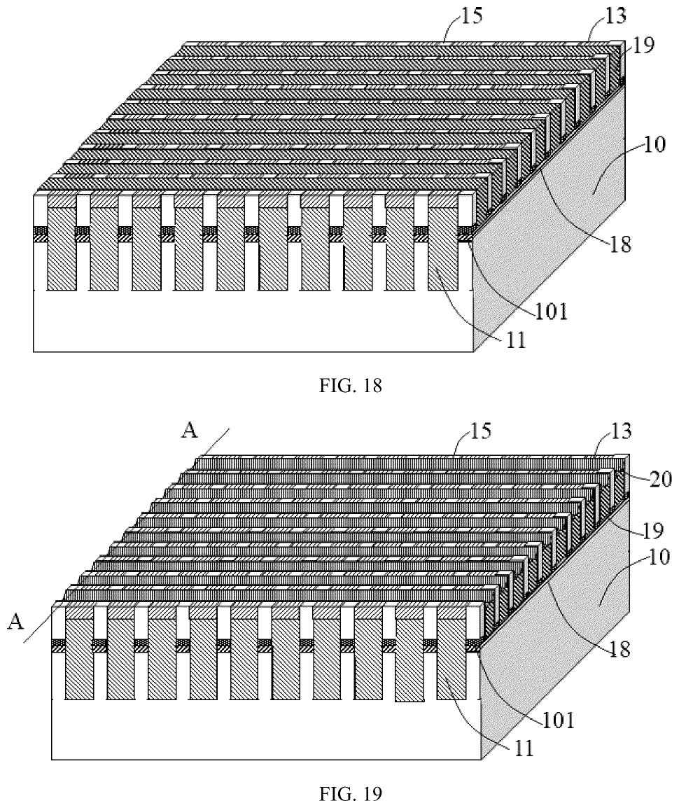

Please refer to FIG. 14 and FIG. 18, In one or more exemplary embodiments of the present application, after the source 18 is formed, an insulating medium is deposited in the groove 14 until the insulating medium completely fills the groove 14. In one or more embodiments, the insulating medium is made of the same material as that of the protective layer 16. For example, the insulating medium is made of silicon oxide. The present application does not limit the deposition method of the insulating medium. For example, the insulating medium is be formed in the groove 14 by deposition methods such as chemical vapor deposition or high aspect ratio chemical vapor deposition. After the insulating medium is deposited, the insulating medium is planarized by a planarizing process, such as chemical mechanical polishing, with the substrate 10 as a grinding stop layer, to obtain a second isolation structure 19. At this time, the upper surface of the second isolation structure 19 is flush with the upper surface of the substrate 10. In one or more embodiments, the second isolation structure 19 is arranged vertically to and crosswise with respect to the first isolation structure 11, and the depth of the second isolation structure 19 is less than the depth of the first isolation structure 11.

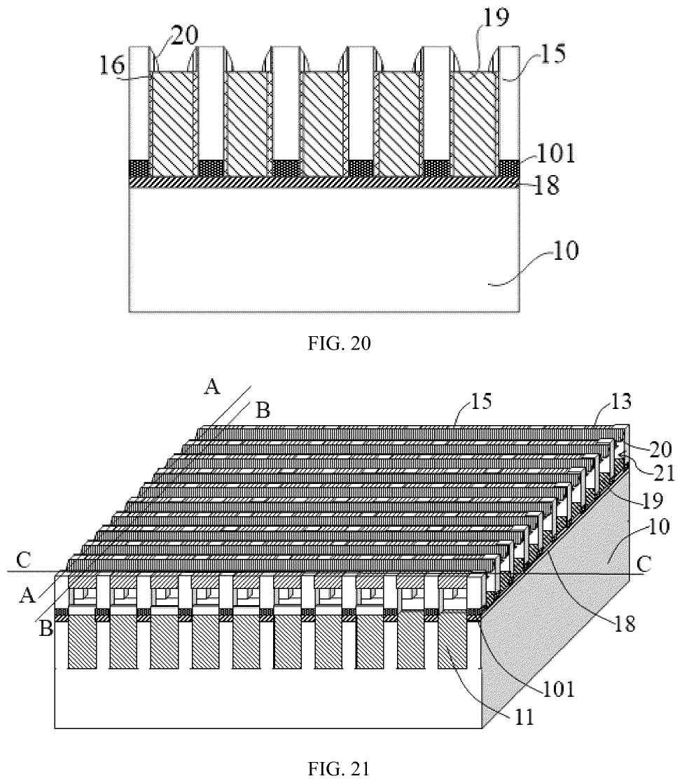

Please refer to FIG. 18 and FIG. 20, FIG. 20 is a cross-sectional view of FIG. 19 in a direction A-A. After the second isolation structure 19 is formed, the second isolation structure 19 is etched back so that the surface of the second isolation structure 19 is lower than the surface of the substrate 10, forming a second recess (not shown in the figure). In one or more exemplary embodiments, since the second isolation structure 19 is made of a material that is different from the material of the hard mask layer 13 on the substrate 10 and the first isolation structure 11 but is the same as the material of the protective layer 16, for example, selective dry etching or selective wet etching is used to remove only the top part of the second isolation structure 19 and the protective layer 16, and the substrate 10 and the hard mask layer 13 are not etched. In one or more exemplary embodiments, after the second isolation structure 19 and the protective layer 16 are etched back, the surface of the second isolation structure 19 and the protective layer 16 is, for example, flush with the surface of the first isolation structure 11, that is, the depth of the second recess is equal to the depth of the first recess formed in the above-mentioned step. In one or more exemplary embodiments, the depth of the second recess may also be different from that of the first recess.

Please refer to FIG. 19 and FIG. 20, In one or more exemplary embodiments of the present application, after the second isolation structure 19 and the protective layer 16 are etched back, a spacer structure 20 is formed on the side of the vertical channel 15 exposed in the second recess. Specifically, a spacer dielectric layer (not shown in the figure) is formed on the sidewall and the bottom of the second recess and the top of the substrate 10. The spacer dielectric layer is, for example, a stacked structure of one or more of silicon oxide, silicon nitride, and silicon oxynitride. The spacer dielectric layer is etched to retain only the spacer dielectric layer on the side of the vertical channel 15 in the second recess to form the spacer structure 20. In one or more exemplary embodiments, the top of the spacer structure 20 is, for example, flush with the top surface of the vertical channel 15. The spacer structure 20 is, for example, arc-shaped. Adjacent spacer structures 20 are not connected, exposing a part of the second isolation structure 19. By forming the spacer structure, in the subsequent preparation process, the top part of the vertical channel 15 is protected for forming a drain.

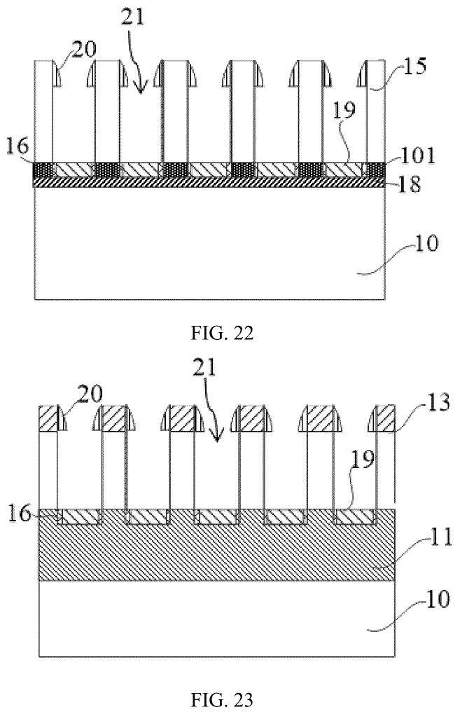

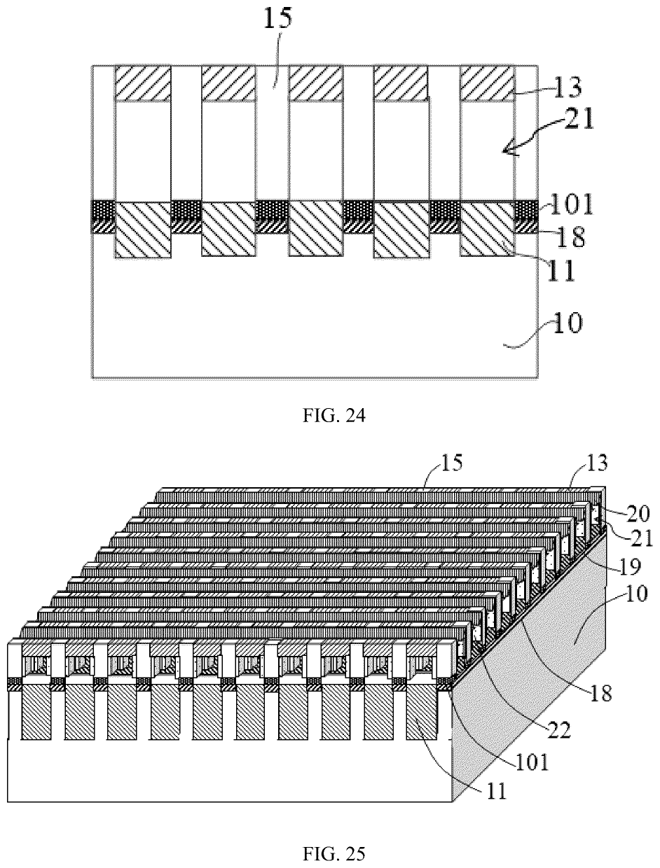

Please refer to FIG. 19 to FIG. 24, FIG. 22 is a cross-sectional view of FIG. 21 along a direction A-A, FIG. 23 is a cross-sectional view of FIG. 21 along a direction B-B, and FIG. 24 is a cross-sectional view of FIG. 21 along a direction C-C. After the spacer structure 20 is formed, a part of the second isolation structure 19, a part of the protective layer 16, and a part of the first isolation structure 11 are removed to expose a part of the vertical channel 15 between the spacer structure 20 and the source 18, thereby forming an opening 21. In one or more exemplary embodiments, wet etching is selected to selectively remove a part of the second isolation structure 19, a part of the protective layer 16, and a part of the first isolation structure 11, and for example, hydrofluoric acid or buffered oxide etchant (BOE) is selected. Before etching, the top of the second isolation structure 19, the top of the protective layer 16, and the top of the first isolation structure 11 are at the same level and they are made of the same material. Therefore, after etching, the bottom of the opening 21 is flat. In one or more exemplary embodiments, the bottom of the opening 21 is flush with the surface of the source doping region 101 to ensure the conduction of the device.

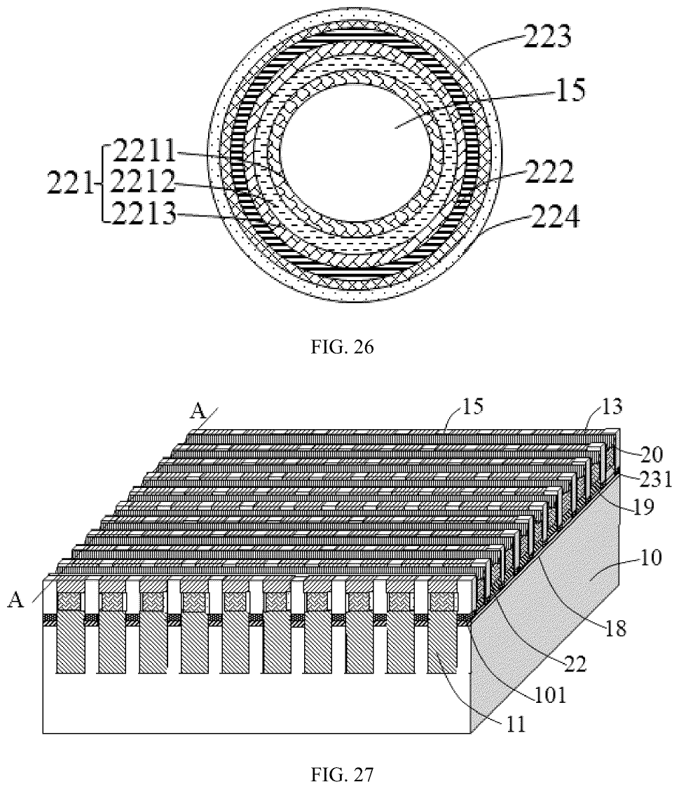

Please refer to FIG. 21, FIG. 25, and FIG. 26, In one or more exemplary embodiments of the present application, after the opening 21 is formed, a gate dielectric layer 22 is formed around the vertical channel 15 exposed by the opening 21. In one or more exemplary embodiments, starting from the surface of the vertical channel, the gate dielectric layer 22 sequentially includes a tunneling layer 221, a storage layer 222, a buffer layer 223, and a barrier layer 224. The tunneling layer 221 includes a first tunneling layer 2211, a second tunneling layer 2212, and a third tunneling layer 2213. The first tunneling layer 2211 and the third tunneling layer 2213 are, for example, silicon oxide layers, and the second tunneling layer 2212 is, for example, a silicon nitride layer. That is, the tunneling layer 221 is a bandgap-engineered ONO structure. The storage layer 222 is, for example, a silicon nitride layer, the buffer layer 223 is, for example, a silicon oxide layer, and the barrier layer 224 is, for example, a layer with a high dielectric constant, such as an aluminum oxide layer. In one or more exemplary embodiments, the tunneling layer 221, the storage layer 222, the buffer layer 223, and the barrier layer 224 are formed by methods such as atomic layer deposition, etc. The thickness of the tunneling layer 221, the thickness of the storage layer 222, the thickness of the buffer layer 223, and the thickness of the barrier layer 224 are selected according to the design requirements of the semiconductor device to meet the performance requirements of the memory. In one or more exemplary embodiments, by providing the tunneling layer 221 of the ONO structure, the tunnel barrier of the ONO structure may improve the hole tunneling efficiency, improve the erasing speed, and reduce the erasing saturation, thereby improving the reliability of the tunneling layer. In one or more exemplary embodiments, the barrier layer 224 may reduce gate injection during the erasing process. The buffer layer 223 is arranged between the barrier layer 224 and the storage layer 222, which may reduce charge leakage and improve the reliability of the memory.

Please refer to FIG. 25 and FIG. 27, In one or more exemplary embodiments of the present application, after the gate dielectric layer 22 is formed, a metal material is deposited in the opening 21 until the metal material completely fills the opening 21 to form a metal material layer 231. The metal material layer 231 is deposited, for example, by plasma enhanced chemical vapor deposition, high density plasma chemical vapor deposition, atomic layer deposition, physical vapor deposition, or the like. The deposited metal material is, for example, tungsten, copper, aluminum, titanium, or the like. After the deposition is completed, the metal material layer 231 is planarized by a planarizing process such as chemical mechanical polishing with the substrate 10 as a grinding stop layer, and then the metal material between the spacer structures is removed by selective etching, so that the top of the metal material layer 231 is flush with the top of the gate dielectric layer 22. In one or more embodiments of the present application, multiple photoresists may be reduced through multiple selective etchings, costs may be reduced greatly, and production efficiency may be improved.

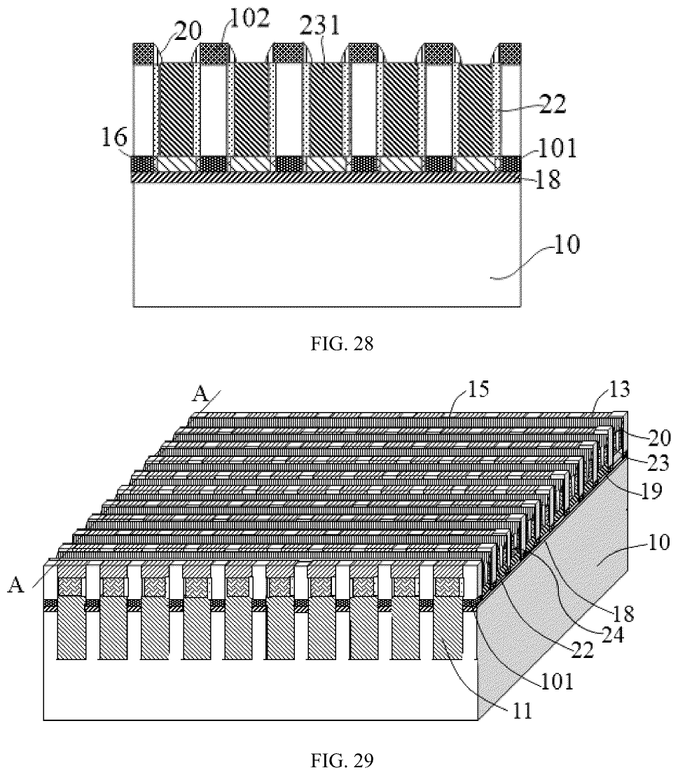

Please refer to FIG. 27 to FIG. 28, FIG. 28 is a cross-sectional view of FIG. 27 along a direction A-A. After the metal material layer 231 is formed, the vertical channel 15 is doped to form a drain doping region 102, and then the dopant ions are activated by rapid high-temperature thermal annealing to reduce the resistance of the drain formed subsequently. In one or more exemplary embodiments, the type of the dopant ions in the drain doping region 102 is opposite to the doping type of the substrate 10. The doping concentration of the drain doping region 102 is, for example, equal to the doping concentration of the source doping region 101. In one or more exemplary embodiments, the drain doping region 102 is formed, for example, by ion implantation technology, and the implantation depth and the implantation range of the drain doping region 102 are controlled by controlling the implantation energy. In one or more exemplary embodiments, the depth of the drain doping region 102 is, for example, equal to the depth of the spacer structure, that is, the plane where the bottom of the drain doping region 102 is located coincides with the plane where the top of the metal material layer 231 is located.

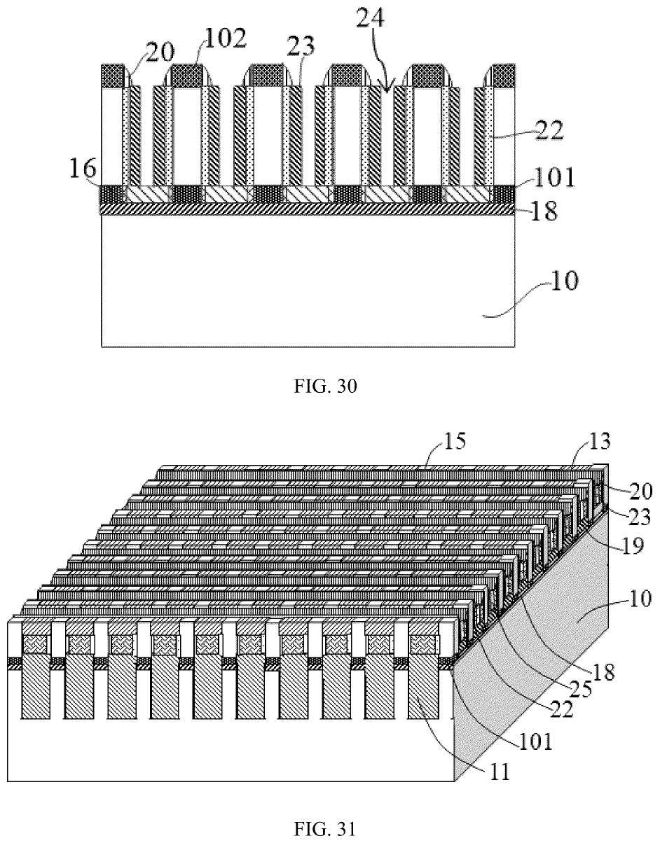

Please refer to FIG. 28 to FIG. 31, FIG. 30 is a cross-sectional view of FIG. 29 along a direction A-A. After the drain doping region 102 is formed, a part of the metal material layer 231 is etched to form an elongated gap 24 in a direction perpendicular to the source 18, to break the metal material layer 231 between the memory units in different rows is to form a metal gate 23. An insulating material layer 25 is deposited in the gap 24. The insulating material layer 25 is made of, for example, silicon oxide, silicon nitride, or the like, and is formed by, for example, chemical vapor deposition or physical vapor deposition. After the insulating material layer 25 is formed, the insulating material layer 25 is planarized, such that the upper surface of the insulating material layer 25 is not higher than the upper surface of the substrate 10. The metal gate 23 surrounds the vertical channel 15 to form a Gate-All-Around (GAA) structure, which may make the electric field distribution of the channel more accurate and improve the performance of the memory.

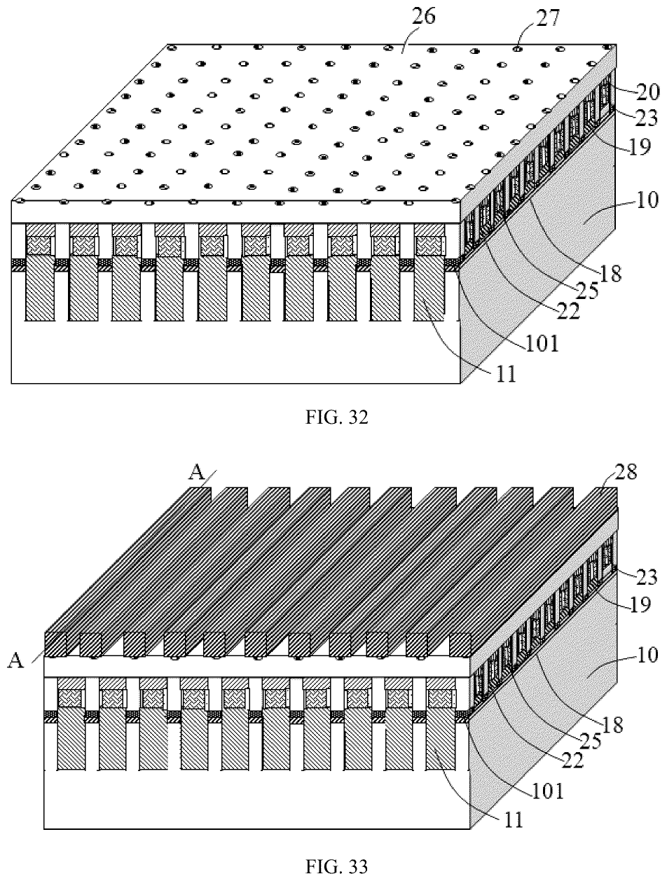

Please refer to FIG. 31 and FIG. 32, In one or more exemplary embodiments of the present application, after the insulating material layer 25 is formed, an interlayer dielectric layer 26 is formed on the substrate 10. The interlayer dielectric layer 26 is, for example, silicon oxide or a material with a low dielectric constant (Low-K). The material with a low dielectric constant is, for example, one of silicon fluoride, silicon oxycarbide, silicon oxyfluoride, or the like, which may improve the reliability of the formed metal plug. The interlayer dielectric layer 26 is formed, for example, by a low-pressure chemical vapor deposition method or a high aspect ratio process, etc., which may improve the filling capacity of the interlayer dielectric layer 26. After the interlayer dielectric layer 26 is deposited, the interlayer dielectric layer 26 is subjected to a planarization process. For example, a part of the interlayer dielectric layer 26 is removed through a chemical mechanical polishing process to ensure that the surface of the interlayer dielectric layer 26 is flat, which may improve the convenience of metal connection. After the interlayer dielectric layer 26 is formed, a plurality of openings (not shown in the figure) are formed in the interlayer dielectric layer 26. In one or more exemplary embodiments, the opening is, for example, located on the vertical channel 15. After the openings are formed, a conductive material is deposited in the openings to form a plurality of conductive plugs 27. The conductive plugs 27 are connected to the drain doping region 102 on the vertical channel 15. During the deposition of the conductive material, a metal barrier layer (not shown in the figure) may be deposited in the opening first, and the metal barrier layer is, for example, a material with good adhesion, such as tantalum (Ta), titanium (Ti), ruthenium (Ru), tantalum nitride (TaN), or titanium nitride (TiN), or the like, which may enhance the adhesion between the conductive material and the sidewall of the opening, reduce the diffusion of the conductive material to the interlayer dielectric layer, reduce the electromigration phenomenon, and improve the electrical performance of the semiconductor structure. The conductive material is, for example, a low-resistance material, such as metal copper, metal aluminum, or metal tungsten. In one or more exemplary embodiments, the conductive material is, for example, metal tungsten. Metal tungsten is formed, for example, by physical vapor deposition, electroplating, or the like, and the metal tungsten is filled in the opening until it covers the interlayer dielectric layer 26, and then the metal tungsten is planarized so that the metal tungsten is flush with the interlayer dielectric layer 26 on both sides of the opening.

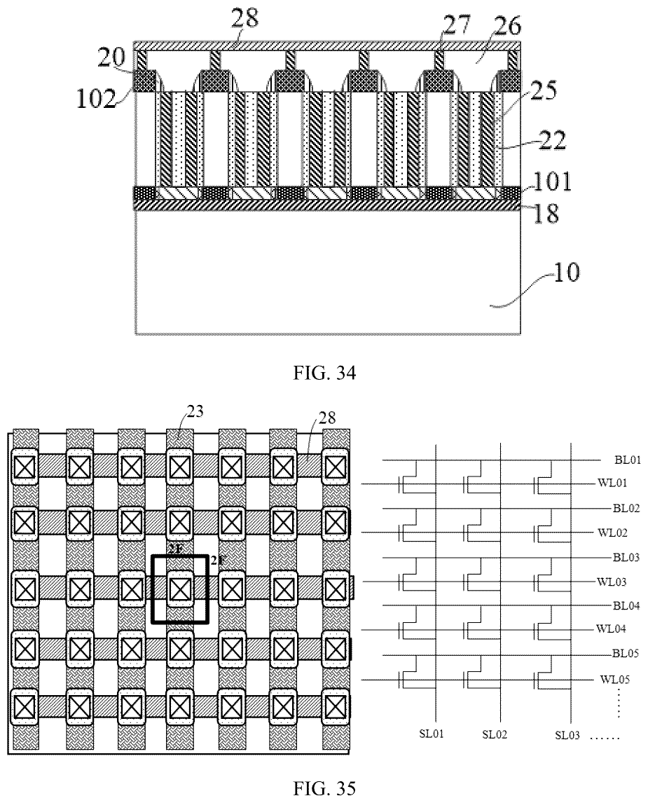

Please refer to FIG. 32 to FIG. 34, In one or more exemplary embodiments of the present application, FIG. 34 is a cross-sectional view of FIG. 33 along a direction A-A. After the conductive plug 27 is formed, a drain 28 is formed on the interlayer dielectric layer 26. For example, a metal material is deposited on the interlayer dielectric layer 26, and then the metal material is etched to form the drain 28. The metal material is, for example, copper, etc., and is deposited by, for example, sputtering, electroplating, chemical plating, or the like. In one or more exemplary embodiments, the drain 28 is in a strip shape and connected to a plurality of conductive plugs 27, the drain 28 is arranged parallel to the source 18, and the metal gate 23 is arranged vertically to the drain 28 and the source 18, which may optimize the layout of the memory and improve the performance of the memory. The metal gate 23 is used as a word line (WL) to control the potential of the gate, the source 18 is used as a source line (SL) to control the potential of the source end, and the drain 28 is used as a bit line (BL) to control the potential of the drain end.

Please refer to FIG. 33 to FIG. 35, In one or more exemplary embodiments of the present application, in the memory formed, a NOR flash memory array with a minimum storage unit area of 4F² can be obtained, which may greatly reduce the unit area of the small NOR flash memory array, so as to improve the density of the NOR flash memory and reduce the cost. To read the data from a specific unit, it is only needed to apply a voltage to the corresponding word line WL to turn on the transistor in the corresponding column, and then a read voltage is applied to the corresponding bit line BL. At this time, there is a current flowing from the bit line BL to the source line SL on the memory of the specified unit. The state of the memory can be obtained by reading the current on the corresponding source line SL. To write data to the specified storage unit, it is only needed to apply a voltage to the corresponding word line WL. At this time, the transistor of the corresponding column is in the on state, and then a write voltage is applied to the corresponding bit line BL or source line SL. The specific application method is determined by the data to be written. At this time, the device is written to the required state.

In summary, the present application provides a method for manufacturing a three-dimensional memory, which may simplify the manufacturing process, eliminate the need for redundant wiring, and improve the connection performance of the three-dimensional memory device. It may reduce multiple photoresists, simplify the manufacturing process, greatly reduce costs, and improve production efficiency. It may reduce the unit area of a small NOR flash memory array to increase the density of NOR flash memory and reduce costs. It may make the electric field distribution of the channel more accurate and improve the performance of the memory. It may improve the hole tunneling efficiency, increase the erasing speed while reducing the erasing saturation, reduce charge leakage, and improve the reliability of the memory. By forming a three-dimensional memory, it is possible to break through the process node limitations, increase the density of flash memory units, and increase the integration of the memory, thereby meeting the application of the memory in the new generation of information technology.

Through the method for manufacturing a three-dimensional memory provided by the present application, the integration of the memory may be improved, the manufacturing process may be simplified, the production cost may be reduced, and the production efficiency may be improved.

Please note, any product implementing the present application does not necessarily need to achieve all of the advantages described above at the same time.

References throughout the specification to “one embodiment,” “an embodiment,” or “a specific embodiment” mean that a particular feature, structure, or characteristic described in connection with the embodiment is included in at least one embodiment of the application, and not necessarily in all embodiments. Thus, various appearances of the phrases “in an embodiment,” “in an embodiment,” or “in a specific embodiment” in different places throughout the specification do not necessarily refer to the same embodiment. In addition, the particular features, structures, or characteristics of any specific embodiment of the application may be combined with one or more other embodiments in any suitable manner. It should be understood that other variations and modifications of the embodiments of the application described and illustrated herein may be possible in light of the teachings herein and are to be considered part of the spirit and scope of the application.

It should also be understood that the embodiments of the present application disclosed above are only used to help illustrate the present application. The embodiments do not describe all the details in detail, nor do they limit the application to the specific embodiments described. Obviously, many modifications and changes can be made according to the content of this specification. This specification selects and specifically describes these embodiments in order to better explain the principles and practical applications of the present application, so that those skilled in the art can well understand and use the present application. The present application is limited only by the claims and their full scope and equivalents.

What is claimed is:

1. A method for manufacturing a three-dimensional memory, comprising:
providing a substrate;
forming a first isolation structure and a second isolation structure in the substrate, wherein the first isolation structure vertically intersects the second isolation structure, a plurality of vertical channels is formed in the substrate, and a depth of the second isolation structure is less than a depth of the first isolation structure;
forming a source in the substrate at a bottom of the second isolation structure, wherein an entire row of the vertical channels shares a same source;
sequentially forming a gate dielectric layer and a metal gate around the vertical channel, wherein the metal gate is distributed vertically to the source; and
forming a drain on the vertical channel, wherein the drain is arranged in parallel with the source.

2. The method for manufacturing a three-dimensional memory according to claim 1, further comprising:
after the first isolation structure is formed, doping the substrate to form a source doping region, wherein a depth of the source doping region is less than a depth of the first isolation structure;
etching back the first isolation structure through selective etching to form a first recess; and
forming a hard mask layer in the first recess.

3. The method for manufacturing a three-dimensional memory according to claim 2, further comprising:
forming a patterned photoresist layer on the substrate and the hard mask layer, wherein a plurality of elongated openings is provided on the patterned photoresist layer, and the elongated openings are perpendicular to the first isolation structure;
etching the substrate and the hard mask layer with the patterned photoresist layer as a mask to form a groove, wherein a bottom of the groove is located in the source doping region;
forming a protective layer on a sidewall of the groove, wherein the protective layer exposes the substrate at the bottom of the groove;
forming a metal layer in the groove;
annealing the metal layer to form the source; and
removing an unreacted part of the metal layer.

4. The method for manufacturing a three-dimensional memory according to claim 3, further comprising:
after the source is formed, depositing an insulating material in the groove to form the second isolation structure;
selectively etching back the second isolation structure and the protective layer, such that a surface of the second isolation structure is lower than a surface of the substrate, so as to form a second recess; and
forming a spacer structure on a sidewall of the vertical channel exposed by the second recess.

5. The method for manufacturing a three-dimensional memory according to claim 4, wherein forming the metal gate includes:
after the spacer structure is formed, removing a part of the second isolation structure, a part of the protective layer, and a part of the first isolation structure to form an opening, wherein a bottom of the opening is flush with a surface of the source doping region;
forming a gate dielectric layer around the vertical channel exposed by the opening;
completely filling the opening with a metal material layer; and
etching the metal material layer along a direction perpendicular to the first isolation structure to form the metal gate.

6. The method for manufacturing a three-dimensional memory according to claim 5, wherein forming the drain includes:
after the opening is filled with the metal material layer, doping an end of the vertical channel away from the source to form a drain doping region;
after the metal gates are formed, forming an insulating material layer between the metal gates, and forming an interlayer dielectric layer on the insulating material layer, the metal gates, and the substrate;
forming a conductive plug in the interlayer dielectric layer, wherein the conductive plug is connected to the drain doped region; and
forming the drain on the interlayer dielectric layer and the conductive plug, and the entire row of the vertical channels shares the drain.

7. The method for manufacturing a three-dimensional memory according to claim 6, wherein
a plane where a bottom of the drain doping region is located coincides with a plane where a top of the metal gate is located,
a doping type of the drain doping region and a doping type of the source doping region are opposite to a doping type of the vertical channel, and
the drain doping region and the source doping region have a same doping concentration.

8. The method for manufacturing a three-dimensional memory according to claim 1, wherein a minimum area of a storage unit of the memory is 4F².

9. The method for manufacturing a three-dimensional memory according to claim 1, wherein
starting from a surface of the vertical channel, the gate dielectric layer sequentially includes a tunneling layer, a storage layer, a buffer layer, and a blocking layer.

10. The method for manufacturing a three-dimensional memory according to claim 9, wherein
the tunneling layer includes a first tunneling layer, a second tunneling layer, and a third tunneling layer formed in sequence,
the first tunneling layer, the third tunneling layer, and the buffer layer are silicon oxide layers,
the second tunneling layer and the storage layer are silicon nitride layers, and the barrier layer is an aluminum oxide layer.
